(19) United States
(12) Patent Application Publication
(10) Pub. No.: US 2006/0093730 A1
(43) Pub. Date: May 4, 2006

(54) Monitoring a flow distribution of an energized gas

(75) Inventors: See-Eng Phan, San Jose, CA (US); Ralf Hofmann, Soquel, CA (US); Tong Zhang, Palo Alto, CA (US); Yehuda Demayo, San Jose, CA (US); Sreekrishnan Sankaranarayanan, Santa Clara, CA (US); Chiukin Steven Lai, Sunnyvale, CA (US)

Correspondence Address: APPLIED MATERIALS, INC.;Patent Department, M/S 2061, P.O. Box 450A, Santa Clara, CA, 95052, US

(73) Assignee: Applied Materials, Inc.

(21) Appl. No.: 10/980,966

(22) Filed: Nov. 3, 2004

(51) Int. Cl. C23C 16/52; C23C 16/00

(52) U.S. Cl. 427/8; 427/248.1

(57) ABSTRACT

A method of detecting a property of an energized gas in a process chamber involves providing a substrate having a hydride precursor in the chamber. The substrate is exposed to an energized gas comprising hydrogen in the chamber to form a hydride compound in the precursor layer. A sheet resistance of the layer is measured to determine the property of the energized gas, such as at least one of the processing uniformity and cleaning ability of the energized gas. One or more process parameters can be selected in relation to the measured sheet resistance to improve the energized gas processing uniformity and cleaning ability.

### BACKGROUND

Embodiments of the present invention relate to measuring properties of an energized process gas, such as a flow distribution, in the processing of a substrate.

In the processing of substrates, such as semiconductors or display, materials are deposited on the substrate and etched to form electrically conducting interconnects, contacts, and vias. For example, a pattern of electrical interconnect lines can be formed by depositing a metal-containing conductor on the substrate, forming a resist pattern on the conductor, etching the conductor to form the interconnect lines, and then depositing a dielectric layer over the etched interconnect lines. The dielectric layer can be further etched to form contact holes or vias that expose the underlying metal-containing conductor material or other substrate regions, respectively. Electrically conducting material is then deposited into the etched holes to electrically contact the underlying conductor. For example, in the formation of copper-containing interconnects, the dielectric layer can be etched to form contact holes that expose an underlying copper conductor material. A thin seed layer of copper may then be deposited over the exposed copper conductor material and surfaces of the contact hole to facilitate a subsequent copper electroplating process that at least partially fills the contact hole.

However, the metal-containing conductor material can comprise deposits of material that require cleaning before subsequent process steps can be performed. For example, the deposits can comprise a native oxide film that forms when the conductor is exposed to oxygen species during an intermediate process step. The native oxide films are undesirable because they increase the electrical resistance at the contact interface between the exposed conductor surface and the subsequently deposited electrically conducting material. The native oxide film can be removed from the metal-containing conductor in a “pre-cleaning” process performed before deposition of the electrically conducting material on the exposed conductor surface. One example of pre-cleaning process is described in U.S. patent application Ser. No. 10/778,898 to Wood et al, filed on Feb. 12, 2004 and commonly assigned to Applied Materials, which is herein incorporated by reference in its entirety. In one version, the pre-cleaning process involves exposing the substrate to a remotely-energized hydrogen-containing gas comprising hydrogen radicals that provide a relatively gentle clean of the native oxide and other materials from the surface.

Before a pre-cleaning process is performed, the energized gas formed in the process chamber is directly or indirectly analyzed to ascertain qualities such as the processing uniformity of the energized gas in the chamber. A uniform flow distribution of energized species across the surface of the substrate provides more uniform cleaning across the substrate and avoids over or under-cleaning of regions of the substrate. In one method of determining the flow processing uniformity of the energized gas species across a substrate, a copper test substrate comprising a surface layer of copper oxide is placed in the chamber and a pre-cleaning process is performed to reduce the copper oxide to elemental copper. The copper test substrate is then removed from the chamber, and the reflectivity of the reduced copper is measured across the test substrate surface to determine the processing uniformity and effectiveness of the cleaning process. However, this type of testing is not economical for regular use, as copper test substrates can be expensive and difficult to procure. Also, the copper oxide layer formed on such test substrates typically varies in thickness from substrate to substrate, making it difficult to achieve reproducible results or make comparisons between pre-cleaning processes. In yet another version, a test substrate having a layer of photoresist is processed in the pre-cleaning process, and the degree of photoresist removal is monitored to determined the cleaning ability and processing uniformity of the cleaning process. However, this method may be undesirable because photoresist residues can deposit on surfaces in the pre-cleaning chamber, and can contaminate subsequent production substrates that are cleaned in the chamber.

Thus, it is desirable to be able to determine properties of an energized gas across a substrate that affect processing uniformity. It is further desirable to determine the processing uniformity of energized gas species across a substrate, and consequently, the cleaning processing uniformity of the energized gas, cost-effectively and without contaminating the process chamber.

### SUMMARY

In one version, a method of detecting a property of an energized gas in a process chamber is provided that involves providing a substrate having a hydride precursor in the chamber. The substrate is exposed to an energized gas comprising hydrogen in the chamber to form a hydride compound in the precursor layer. A sheet resistance of the layer is measured to determine the property of the energized gas, such as a flow distribution or cleaning processing uniformity of the energized gas. One or more process parameters, such as at least one of (i) a gas energizing power level, (ii) a pressure, (iii) a gas flow rate, (iv) a temperature in the chamber, and (v) an electrode spacing, can be selected in relation to the sheet resistance to improve the processing uniformity or cleaning ability of the energized gas.

In another version, a method of processing a substrate in a substrate processing chamber includes a pre-processing step in which a test substrate having a hydride precursor layer is provided in the chamber. The test substrate is exposed to an energized gas comprising hydrogen to form a hydride compound in the precursor layer, and a sheet resistance of the layer is measured. During a processing step, a production substrate is provided in the process chamber. One or more process parameters are selected in relation to the measured sheet resistance, the parameters including at least one of (i) a gas energizing power level, (ii) a pressure, (iii) a gas flow rate, (iv) a temperature in the chamber, and (v) an electrode spacing. The selected process parameters are maintained while exposing the substrate to energized gas in the chamber to process the production substrate.

In yet another version, a substrate processing chamber is used to process a substrate in an energized gas. The chamber has a support to receive a substrate, a gas supply to provide a gas in the chamber, a gas energizer to energize the gas to process the substrate, a gas exhaust to exhaust gas from the chamber, and a controller comprising computer program code to send control signals to control the support, gas supply, gas energizer and gas exhaust. The computer program code includes pre-processing program code to provide a test substrate in the chamber, the test substrate having a hydride precursor layer with material that is capable of forming a hydride compound that changes a sheet resistivity of the detection layer. The pre-processing program code is capable of exposing the test substrate to an energized gas comprising hydrogen to form a hydride compound in the layer. The computer program code further includes monitoring program code to receive an input signal in relation to a measured sheet resistance of the layer, and select one or more process parameters in relation to the measured sheet resistance, the parameters including at least one of (i) a gas energizing power level, (ii) a pressure, (iii) a gas flow rate, (iv) a temperature in the chamber, and (v) an electrode spacing. The computer program code also includes processing program code to provide a production substrate in the process chamber, and maintain the selected process parameters while exposing the production substrate to energized gas in the chamber to process the production substrate.

### DRAWINGS

These features, aspects, and advantages of the present invention will become better understood with regard to the following description, appended claims, and accompanying drawings, which illustrate examples of the invention. However, it is to be understood that each of the features can be used in the invention in general, not merely in the context of the particular drawings, and the invention includes any combination of these features, where:

FIG. 1 is a sectional side view of an embodiment of a test substrate having a hydride precursor layer and a sheet resistance detector;

FIG. 2 is a sectional side view of an embodiment of an apparatus comprising a pre-cleaning chamber;

FIG. 3 is a sectional side view of an embodiment of a production substrate having a metal-containing conductor and dielectric layer; and

FIG. 4 is an illustrative block diagram of a controller comprising a computer readable program.

### DESCRIPTION

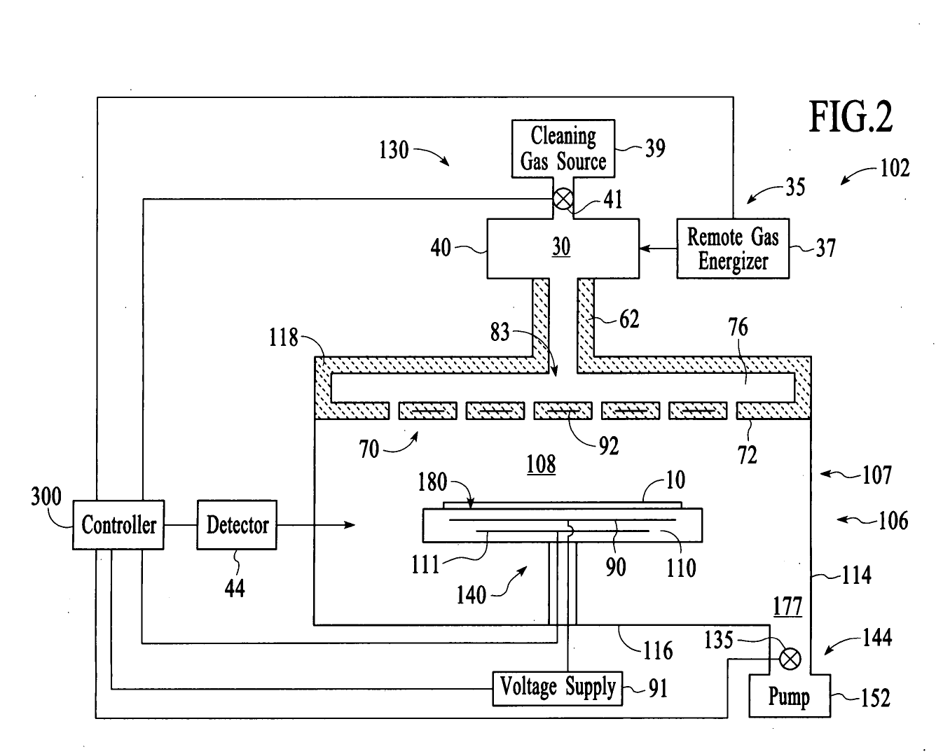

A method of determining a property of an energized gas in a process chamber 106, such as the pre-clean chamber shown in FIG. 2, comprises processing a test substrate 10a comprising a hydride-precursor layer 24 in the chamber 106. The method may be especially useful for determining the processing uniformity of an energized process gas in the chamber 106. The processing uniformity of the energized process gas across the substrate surface affects the rate and extent to which the substrate is processed by the gas. The processing uniformity of the energized gas is a measure of the deviation of energized gas characteristics, such as the flow distribution, energy, and density of the energized gas, at various points across the diameter of the substrate. A highly uniform energized gas has very little deviation in these characteristics at different points across the substrate, whereas a non-uniform energized gas has a high degree of variation across the substrate. The cleaning ability of the energized gas is a measure of the ability of the energized gas to clean material from the substrate, such as the cleaning rate of the energized gas. Processing of the test substrate 10a allows the processing uniformity and cleaning ability of the energized gas to be measured to check that the energized gas is substantially uniform and provides good cleaning results before cleaning of a production substrate 10b.

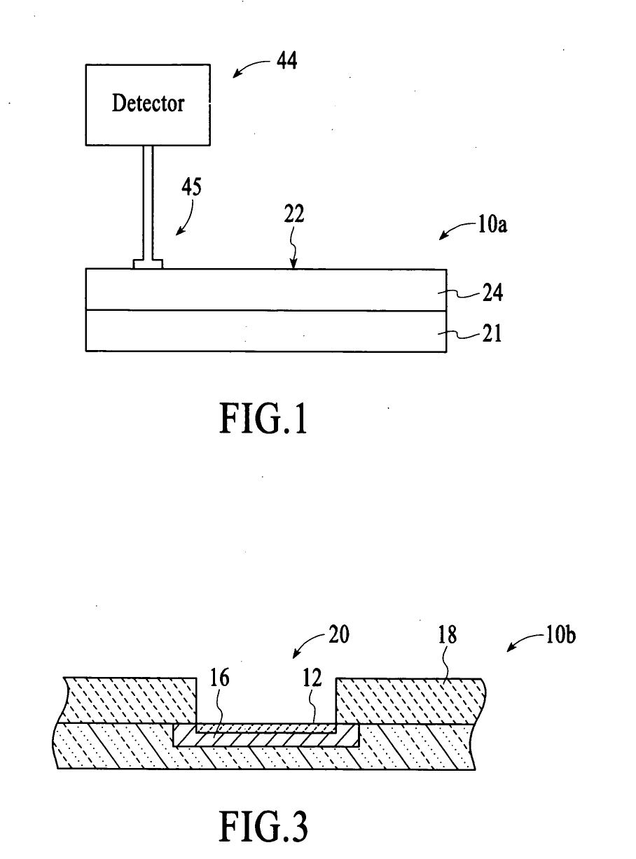

The test substrate 10a comprises a hydride-precursor layer 24 comprising a hydride-precursor material that is capable of forming a hydride-compound upon exposure to the energized gas, as shown in FIG. 1. For example, a suitable hydride-precursor material may be a metal-containing material, such as at least one of titanium, nickel and tantalum. In one version, the hydride-precursor material comprises titanium metal that forms titanium hydride upon exposure to an energized gas comprising hydrogen. The test substrate 10a desirably comprises the hydride precursor layer 24 at a surface 22 of the substrate 10a that is exposed to the energized gas. In one version, the test substrate 10a comprises a semiconductor substrate 21 having a layer 24 of hydride-precursor material formed thereon, as shown for example in FIG. 1. The hydride-precursor layer 24 may comprise a thickness of from about 100 angstroms to about 500 angstroms, such as from about 200 angstroms to about 400 angstroms. Alternatively, the test substrate 10a may be substantially entirely composed of the hydride-precursor layer 24.

The test substrate 10a is exposed to an energized gas comprising hydrogen-containing gas to form hydride compounds in the precursor layer 24. The energized hydrogen-containing gas chemically reacts with the hydride-precursor material to convert the hydride-precursor material to hydride compounds at the surface 22 of the test substrate. Hydrogen-containing gases that are capable of forming the hydride compounds may comprise, for example, at least one of H₂, H₂O and NH₃. The energized gas desirably comprises a composition that is substantially similar to that used to process the production substrates 10b, in order to accurately determine the energized gas processing uniformity under the processing conditions. In one version, the energized gas used to process test substrates and production substrates comprises a composition of H₂ and at least one of H₂O and He. For example, the energized gas can comprise from about 0 to about 2000 sccm of H₂, about 0 to about 280 sccm of He, and from about 0 to about 20 sccm of H₂O.

The energized gas can be formed by coupling electromagnetic energy to the hydrogen-containing gas to form energized gas species, such as at least one of energized ionic, dissociated and radical gas species. In one version, the energized gas is formed by coupling RF energy to the gas, for example by capacitively or inductively coupling. In another version, the energized gas is formed by coupling microwave energy to the gas to form energized gas species that are activated or dissociated. The RF or microwave energy can be coupled to the gas in the process chamber, and can also or alternatively be coupled to the gas in a remote zone 30 that is located at a distance away from the process chamber 106, as shown for example in FIG. 2. For example, in the version described in U.S. patent application Ser. No. 10/778,898 to Wood et al, filed on Feb. 12, 2004 and commonly assigned to Applied Materials, which is herein incorporated by reference in its entirety, electromagnetic energy is coupled to a hydrogen-containing gas in a remote zone 30 to form an energized process gas comprising a relatively high concentration of hydrogen-containing radical species. The energized gas comprising the hydrogen-containing radical species provides improved results in pre-cleaning processes by providing a relatively gentler cleaning process to remove deposits from a production substrate 10b. The test substrate 10a can be exposed to the remotely energized hydrogen-containing gas to simulate pre-cleaning process conditions and determine the processing uniformity of the energized gas in the chamber 106.

After the test substrate 10a has been exposed to the energized hydrogen-containing gas for a sufficient period of time, the extent of the hydride compound formation in the precursor layer 24 of the test substrate 10a is determined. The amount of the hydride compounds formed at different points on the test substrate 10a is a measure of the processing uniformity of the energized gas during processing of the test substrate, as a uniform energized gas should form substantially equal amounts of the hydride compound across the substrate 10a. The amount of hydride compounds formed at each point also gives a measure of the cleaning ability and reactivity of the energized gas, as an energized gas having a greater cleaning ability will form a larger amount of hydride compounds at points on the test substrate 10a. In one version, a value related to the resistivity of the precursor layer 24, such as the sheet resistance (Rs) of the precursor layer 24, is measured to determine the extent of hydride compound formation. The sheet resistance (Rs) is a function of the resistivity (p) of the precursor layer 24 divided by the thickness (t) of the precursor layer 24 at a point on the test substrate. Because the resistivity of the precursor layer 24 changes when hydride compounds are formed, and the precursor layer thickness remains substantially unchanged during processing, the sheet resistance provides a measure of the extent to which the measured region of the test substrate 10a has been processed. In one version, the sheet resistance is measured at a plurality of points across the surface 22 of the test substrate 10a, to provide a sheet resistance profile of the precursor layer 24. For example, the sheet resistance can be measured at multiple points on the substrate, at radii that correspond to a ratio of the measured point radius to the substrate radius of about 0.32, 0.64, and 0.97, to provide the sheet resistivity profile. The sheet resistance at one or a plurality of points can also be measured before exposing the test substrate 10a to the energized hydrogen-containing gas, to provide a measure of the change in the sheet resistance at each point after the energized gas exposure. The sheet resistance of the precursor layer 24 provides a measure of the processing uniformity of the energized gas over the test substrate 10a, allowing the energized gas to be tested for sufficient processing uniformity as well as cleaning ability before processing of a production substrate 104.

The sheet resistance can be measured using sheet resistance detector 44 comprising a probe 45. In general, the sheet resistance detector 44 comprises a probe 45 capable of passing a current through the precursor layer 24 at a specified region of the test substrate 10a. Characteristics of the current, such as the amplitude of the current or the associated voltage, are measured to determine the sheet resistance (Rs) in that region. The probe 45 can be moved to different regions of the substrate to obtain a sheet resistance profile of the precursor layer 24 across the test substrate 10a. A suitable sheet resistance detector 44 may be, for example, a four point probe sheet resistance measurement system available from Creative Design Engineering, Inc. in Cupertino, Calif.

In one version, one or more process parameters may be selected in relation to the measured sheet resistance of the test substrate 10a, for example to provide an energized gas that is more uniform in the chamber 106 for the processing of a production substrate 10b. The process parameters may also be selected in relation to the measured sheet resistance to provide an energized gas having an improved cleaning ability, such as a higher cleaning rate. The process parameters that can be selected to provide the improved energized gas properties may be at least one of: (i) a gas energizing power level applied to energize the process gas; (ii) a pressure in the chamber 106; (iii) a flow rate of one or more components of the process gas; (iv) a temperature of a surface in the chamber 106, and (v) a spacing of electrodes 90,92 in the chamber 106. The process parameters can be selected to modify the energized gas such that a more uniform gas distribution and energy is provided. The sheet resistance of the test substrate 10a may also be measured to test for faults in the chamber 106, such as chamber leaks or excessive process residue deposits on surfaces in the chamber 106. Furthermore, new chamber components and designs can also be evaluated with the test substrate 10a to determine whether sufficient processing results, such as the desired processing uniformity or cleaning ability, is provided.

In one version of a pre-processing step to evaluate the energized gas in a chamber 106, a test substrate 10a comprising a titanium layer 24 is provided in a process chamber 106. A hydrogen-containing gas is energized in a remote zone by inductively coupling RF energy at a power level of from about 100 to about 2000 Watts. The hydrogen-containing gas comprises from about 100 sccm to about 200 sccm of H₂, from about 20 sccm to about 300 sccm of He, and from about 0 to about 20 sccm of H₂O. A pressure of gas in the chamber 106 is maintained at from about 20 to about 1000 mTorr. An electrode 90 below the test substrate 10a can be electrically biased by applying a power level of from about 100 to about 1000 Watts. The sheet resistance of the titanium layer 24 is measured before and after the pre-processing step at from about 20 to about 100 points across the test substrate 10a, such as at 49 points, to determine the processing uniformity and cleaning ability of the energized gas during the process. While this process is an exemplary version of a pre-processing step suitable for a pre-cleaning process, it should be understood that the pre-processing step can comprise other processing parameters that are suitable for processes other than pre-cleaning processes, such as etching and deposition process, and may also comprise parameters for pre-cleaning processes other than those described.

The processing parameters can then be selected to provide a uniform energized gas for the processing of production substrates 10b. In one version, a production substrate 10b that is processed after the pre-processing step comprises an underlying metal-containing conductor 16, such as a copper conductor 16, over which a dielectric layer 18, such as a low-k dielectric, is formed, as shown in FIG. 3. The dielectric layer 18 comprises features 20 therein that expose the surface 14 of the metal-containing conductor 16. The metal-containing conductor 16 comprises deposits 12 thereon that are cleaned in the pre-cleaning process, such as native oxide and polymer-containing deposits. The pre-cleaning process cleans the metal-containing conductor surface to allow good electrical contact between the cleaned surface and subsequent materials deposited on the production substrate 10b. The pre-cleaning process comprises exposing the production substrate 10b to energized process gas while maintaining the process parameters selected in relation to the measured sheet resistance of the test substrate 10a. The selected process parameters may be substantially the same as those used to process the test substrate 10a, or may be changed as needed to provide improved processing of the production substrates 104. For example, the production substrate 10b may be exposed to an energized gas comprising a hydrogen-containing gas, such as H₂ and at least one of H₂O and He, under process conditions selected to provide improved cleaning and processing uniformity.

An embodiment of an apparatus 102 comprising a pre-cleaning chamber 106 suitable for processing substrates 10 such as test and production substrates 10,b is shown in FIG. 2. The particular embodiment of the apparatus 102 shown herein is suitable for cleaning substrates 10, such as semiconductor wafers, and may be adapted by those of ordinary skill to clean other substrates 10, such as flat panel displays, polymer panels, or other electrical circuit receiving structures. An example of a pre-cleaning chamber is described in U.S. patent application Ser. No. 10/778,898 to Wood et al, filed on Feb. 12, 2004, and entitled “Cleaning of Native Oxide with Hydrogen-Containing Radicals”, which is herein incorporated by reference in its entirety. Generally, the cleaning chamber 106 comprises one or more walls 107, such as an enclosure wall, which can comprise a ceiling 118, sidewalls 114, and a bottom wall 116 that enclose a process zone 108. Energized cleaning gas is provided to the process zone 108 by a gas supply 130 comprising the remote source 35 and a gas distributor 70. The cleaning gas is energized by the remote source 35 and received by the gas distributor 70 via a connecting conduit 62 having an inlet 83. The gas distributor 70 can comprise a gas distribution plate 72 having apertures 71 therein to distribute the gas in the process zone 108. The gas distributor 70 can also optionally comprise one or more conduits around a periphery of the substrate 10. Spent gas and byproducts are exhausted from the chamber 106 through an exhaust system 144 which may include an exhaust port 177 that receives gas from the process zone 108, and can also include a throttle valve 135 to control the pressure of gas in the chamber 106a, and one or more exhaust pumps 152, such as a turbo-molecular exhaust pump. The exhaust system 144 can be capable of maintaining a sub-atmospheric pressure in the chamber 106.

A remote source 35 suitable for remotely energizing the cleaning gas comprises a remote chamber 40 having the remote zone 30, a cleaning gas source 39 and a remote gas energizer 37. In operation, the cleaning gas is received from the cleaning gas source 39 in the remote chamber 40. A flow valve 41 can be provided to control a flow rate of the cleaning gas into the remote chamber 40. The remote gas energizer 37 couples energy to the cleaning gas in the remote zone 30, which forms an energized cleaning gas comprising energized ionic and radical species. The remote gas energizer 37 can couple, for example, at least one of RF and microwave energy to the cleaning gas. In one version, the remote gas energizer 37 comprises an inductor antenna that inductively couples RF energy to the cleaning gas in the remote zone 30. A suitable RF power level to couple to the cleaning gas may be from about 100 Watts to about 10 kWatts. In another version, the remote gas energizer 37 comprises a toroidal gas energizer to couple energy to the cleaning gas in the remote zone 30, as described for example in U.S. Pat. No. 6,150,628 to Smith et al., herein incorporated by reference in its entirety. A suitable RF power level applied by the toroidal gas energizer may be from about 1000 Watts to about 10,000 Watts. A remote gas energizer 37 comprising a microwave gas activator can also be provided. A suitable microwave power level may be from about 300 Watts to about 5 kWatts. The chamber 106 may also optionally comprise a chamber gas energizer that couples energy to the gas in the process zone 108 of the chamber 106. For example, the chamber gas energizer can comprise one or more of electrodes 90,92 and an inductor antenna to couple RF energy.

The substrate 10 is held in the process zone 108 on a support 110 having a substrate receiving surface 180. The support 110 can optionally comprise an electrode 90 that can be electrically biased by applying a power level from a voltage supply 91. The electrode 90 can be biased to electrostatically hold the substrate 10 on the support 110. The electrode 90 and substrate 10 can also be biased to affect characteristics of the process, such as the degree of ion bombardment of the substrate 10. In one version, the chamber 106 further comprises a second electrode 92 that is capable of capacitively coupling RF energy with the an electrode 90 in the support 110 to a gas in the process zone 108. The second electrode 92 may be in a wall or ceiling of the chamber 106, and may even be in a gas distribution plate 72. The spacing between the first and second electrodes 90, 92 can be selected to provide a desired RF energizing level and density of the energized gas in the process zone 108. In one version, a spacing between electrodes 90,92 can be adjusted by changing a height of the support 110 in the chamber 106. A temperature control system 140 is provided to maintain a temperature of the substrate 10, and can comprise, for example, a resistive heating element 111 in the support 110 beneath the substrate 10. The temperature control system 140 can also comprise one or more other heat-exchanging devices, such as a heat exchange conduit in which heat exchange fluid is provided, and heating lamps. The temperature control system 140 can also comprise a temperature monitor, such as a thermocouple, that monitors the temperature of the substrate 10 and provides a signal in relation to the temperature to a chamber controller 300.

In one version, the apparatus 102 comprises the sheet resistance detector 44 adapted to detect a sheet resistance of the precursor layer 24 on a test substrate 10a. The sheet resistance detector 44 is capable of generating a signal in relation to the measured sheet resistance, which is provided to the controller 300. The signal provided to the controller 300 may be in relation to a magnitude or change in the sheet resistance, and may also be in relation to a sheet resistance profile of the precursor layer 24 across the test substrate 10a.

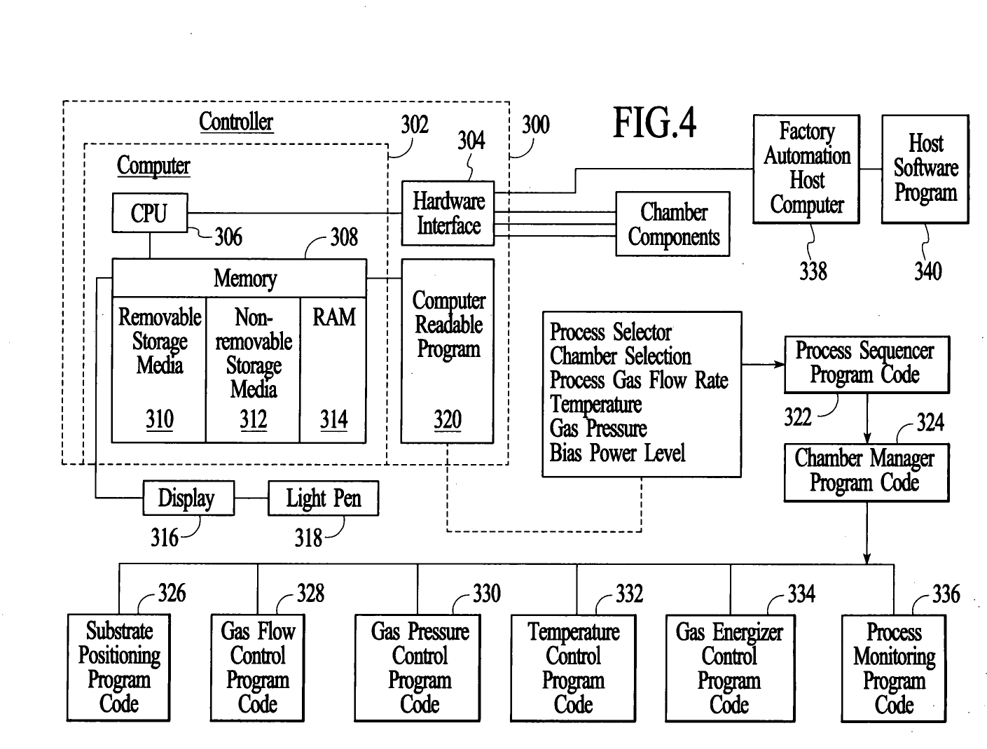

The apparatus 102 can be operated by a controller 300 via a hardware interface 304, as shown in FIG. 4. The controller 300 comprises a computer 302 having a central processor unit (CPU) 306, such as for example a 68040 microprocessor, commercially available from Synergy Microsystems, California, or a Pentium Processor commercially available from Intel Corporation, Santa Clara, Calif., that is coupled to a memory 308 and peripheral computer components. Preferably, the memory 308 may include a removable storage media 310, such as for example a CD or floppy drive, a non-removable storage media 312, such as for example a hard drive, and random access memory 314. The controller 300 may further comprise a plurality of interface cards including, for example, analog and digital input and output boards, interface boards, and motor controller boards. The interface between an operator and the controller 300 can be, for example, via a display 316 and a light pen 318. The light pen 318 detects light emitted by the monitor display 316 with a light sensor in the tip of the light pen 318. To select a particular screen or function, the operator touches a designated area of a screen on the monitor 316 and pushes the button on the light pen 318. Typically, the area touched changes color, or a new menu is displayed, confirming communication between the user and the controller 300.

In one version the controller 300 comprises a computer-readable program 320 may be stored in the memory 308, for example on the non-removable storage media 312 or on the removable storage media 310. The computer readable program 320 generally comprises process control software comprising program code to operate the chambers 106 and its components, process monitoring software to monitor the processes being performed in the chamber 106, safety systems software, and other control software. The computer-readable program 320 may be written in any conventional computer-readable programming language, such as for example, assembly language, C++, or FORTRAN. Suitable program code is entered into a single file, or multiple files, using a conventional text editor and stored or embodied in computer-usable medium of the memory 308. If the entered code text is in a high level language, the code is compiled, and the resultant compiler code is then linked with an object code of precompiled library routines. To execute the linked, compiled object code, the user invokes the object code, causing the CPU 306 to read and execute the code to perform the tasks identified in the program.

An illustrative block diagram of a hierarchical control structure of a specific embodiment of a computer readable program 320 is shown in FIG. 4. Using a light pen or other interface, a user enters a process set and chamber number into the computer readable program 320 in response to menus or screens displayed on the CRT terminal. The computer readable program includes program code to control the substrate position, gas flow, gas pressure, temperature, RF power levels, electrode spacing, and other parameters of a particular process, as well as code to monitor the chamber process. The process sets are predetermined groups of process parameters necessary to carry out specified processes. The process parameters are process conditions, including without limitations, gas composition, gas flow rates, temperature, pressure, gas energizer settings such as RF power levels.

The process sequencer program code 322 comprises program code to accept a chamber type and set of process parameters from the computer readable program 320 and to control its operation. The sequencer program code 322 initiates execution of the process set by passing the particular process parameters to a chamber manager program code 324 that controls multiple processing tasks in the process chamber 106. Typically, the process chamber program code 324 includes a substrate positioning program code 326, a gas flow control program code 328, a gas pressure control program code 330, a temperature control program code 332, a gas energizer control program code 334, and a process monitoring program code 336.

Typically, the substrate positioning program code 326 comprises instructions for controlling chamber components that are used to load the substrate 10 onto the support 110 in the chamber 106, and optionally, to lift the substrate 10 and/or support 110 to a desired height in the chamber 106, for example to provide a desired electrode spacing. The substrate positioning program code 334 can also control a robot in a transfer chamber (not shown) to transfer the substrate 10 between chambers. The gas flow control program code 328 comprises instructions for controlling the flow rates of different constituents of process gas, such as cleaning gas. The gas flow control program code 328 regulates the opening size of one or more gas flow valves 41 to obtain the desired gas flow rate into the chamber 106.

The temperature control program code 332 comprises program code for controlling temperatures in the chamber 106, such as the temperature of the substrate 10a,b. For example, the temperature control program code can control the temperature of a substrate 10 in the pre-cleaning chamber 106 by controlling a current applied to a heater 142, such as the resistive heating element 111 in the support, and monitoring a signal from a temperature sensor to maintain a desired temperature. The gas energizer control program code 334 comprises instructions for controlling gas energizers, such as at least one of the remote gas energizer 37 and chamber electrodes 90,92, for example by setting a power level applied to energize the gas. The process monitoring program code 336 comprises instructions for monitoring the process in the chamber 106, such as for example monitoring the pre-processing step or cleaning process step. The pressure control program code 330 comprises instructions for controlling the pressure in the chamber 106, for example by controlling the throttle valves 135.

In one version, the controller comprises program code to operate the pre-cleaning chamber 106 to process a test substrate 10a, determine the processing uniformity of the energized gas, and select process parameters to perform a pre-cleaning process on a production substrate 10b. For example, the controller 300 can comprise pre-processing program code to provide the test substrate 10a in the chamber 106 and expose the test substrate 10a to an energized gas comprising hydrogen. The process monitoring code 336 can be adapted to receive an input signal that is in relation of the measured sheet resistance of the layer 24, and select one or more process parameters in relation to the measured sheet resistance. For example, the process monitoring code 336 may be capable of selecting at least one of a gas energizing power level, a pressure, a gas flow rate, a temperature and an electrode spacing in the chamber 106 that provides improved energized gas processing uniformity across the production substrate 10b. The controller 300 further comprises processing program code to provide a production substrate 10b in the process chamber 106 and maintain the selected parameters while exposing the production substrate 10b to energized gas in the chamber to process the production substrate 10b, for example to clean the production substrate 10b. Thus, the controller 300 comprises program code that is capable of providing improved processing of the production substrates 10b by selecting parameters according to the measure sheet resistance of the test substrate 10a.

The data signals received by and/or evaluated by the controller 300 may be sent to a factory automation host computer 338. The factory automation host computer 338 may comprise a host software program 340 that evaluates data from several systems, platforms or chambers 106, and for batches of substrates 10 or over an extended period of time, to identify statistical process control parameters of (i) the processes conducted on the substrates 10, (ii) a property that may vary in a statistical relationship across a single substrate 10, or (iii) a property that may vary in a statistical relationship across a batch of substrates 10. The host software program 340 may also use the data for ongoing in-situ process evaluations or for the control of other process parameters. A suitable host software program comprises a WORKSTREAM™ software program available from aforementioned Applied Materials. The factory automation host computer 338 may be further adapted to provide instruction signals to (i) remove particular substrates 10 from the processing sequence, for example, if a substrate property is inadequate or does not fall within a statistically determined range of values, or if a process parameter deviates from an acceptable range; (ii) end processing in a particular chamber 106a-d, or (iii) adjust process conditions upon a determination of an unsuitable property of the substrate 10 or process parameter. The factory automation host computer 338 may also provide the instruction signal at the beginning or end of processing of the substrate 10 in response to evaluation of the data by the host software program 340.

Although exemplary embodiments of the present invention are shown and described, those of ordinary skill in the art may devise other embodiments which incorporate the present invention, and which are also within the scope of the present invention. For example, other processes may be performed on the test and production substrates 10a,b other than those specifically shown. Also, the hydride precursor layer may comprise a material other than that described. Furthermore, relative or positional terms shown with respect to the exemplary embodiments are interchangeable. Therefore, the appended claims should not be limited to the descriptions of the preferred versions, materials, or spatial arrangements described herein to illustrate the invention.

What is claimed is:

1. A method of detecting a property of an energized gas in a process chamber, the method comprising:
(a) providing a substrate in the chamber, the substrate comprising a hydride precursor layer;
(b) exposing the substrate to an energized gas comprising hydrogen, thereby forming a hydride compound in the precursor layer; and
(c) measuring a sheet resistance of the layer to determine a property of the energized gas.

2. A method according to claim 1 wherein (c) comprises determining a property of the energized gas that is a flow distribution of the energized gas across the substrate.

3. A method according to claim 1 wherein (c) comprises determining a property of the energized gas that is a cleaning processing uniformity of the energized gas.

4. A method according to claim 1 wherein (a) comprises providing a substrate comprising a hydride precursor layer having at least one of titanium, nickel, and tantalum.

5. A method according to claim 1 further comprising measuring a sheet resistance of the hydride precursor layer before (b).

6. A method according to claim 1 wherein (c) comprises measuring a sheet resistance profile of the hydride precursor layer at a plurality of points along on the substrate.

7. A method according to claim 1 further comprising selecting one or more parameters of a process in relation to the measured sheet resistance, the parameters including at least one of (i) a gas energizing power level, (ii) a pressure, (iii) a gas flow rate, (iv) a temperature in the chamber, and (v) an electrode spacing.

8. A method according to claim 7 further comprising processing a substrate in the process chamber with the selected parameters.

9. A method of processing a substrate in a substrate processing chamber, the method comprising:
(a) in a pre-processing step:
(i) providing a test substrate in the chamber, the test substrate comprising a hydride precursor layer;
(ii) exposing the test substrate to an energized gas comprising hydrogen, thereby forming the hydride compound in the precursor layer; and
(iii) measuring a sheet resistance of the layer; and
(b) in a processing step:
(i) providing a production substrate in the process chamber;
(ii) selecting one or more process parameters in relation to the measured sheet resistance, the parameters including at least one of (i) a gas energizing power level, (ii) a pressure, (iii) a gas flow rate, (iv) a temperature in the chamber, and (v) an electrode spacing, and;
(iii) maintaining the selected parameters while exposing the substrate to energized gas in the chamber to process the production substrate.

10. A method according to claim 9 wherein (b) comprises selecting one or more process parameters in relation to the measured sheet resistance to provide a substantially uniform flow distribution of energized gas over the production substrate.

11. A method according to claim 9 wherein (b) comprises providing a production substrate comprising a dielectric layer having features therein that expose a copper-containing conductor in the process chamber, and exposing the production substrate to the energized gas to clean the copper-containing conductor.

12. A method according to claim 11 comprising exposing the production substrate to an energized gas comprising H₂ and at least one of He and H₂O.

13. A method according to claim 9 wherein (a) comprises providing a test substrate comprising a hydride precursor layer comprising at least one of titanium, nickel, and tantalum.

14. A method according to claim 9 wherein (a) further comprises comprising measuring a sheet resistance of the hydride precursor layer before exposing the hydride precursor layer to the energized gas.

15. A method according to claim 9 wherein (a) comprises measuring a sheet resistance profile of the hydride precursor layer to determine the flow distribution or cleaning processing uniformity of the energized gas.

16. A substrate processing chamber to process a substrate in an energized gas, the chamber comprising:
(a) a support to receive a substrate;
(b) a gas supply to provide a gas in the chamber;
(c) a gas energizer to energize the gas to process the substrate;
(d) a gas exhaust to exhaust gas from the chamber; and
(e) a controller comprising computer program code to send control signals to control the support, gas supply, gas energizer and gas exhaust, wherein the computer program code comprises:
(i) pre-processing program code to (1) provide a test substrate in the chamber, the test substrate comprising a hydride precursor layer having material that is capable of forming a hydride compound that changes a sheet resistivity of the detection layer, and (2) expose the test substrate to an energized gas comprising hydrogen, thereby forming the hydride compound in the layer;
(ii) monitoring program code to (1) receive an input signal in relation to a measured sheet resistance of the layer, and (2) select one or more process parameters in relation to the measured sheet resistance, the parameters including at least one of (A) a gas energizing power level, (B) a pressure, (C) a gas flow rate, (D) a temperature in the chamber, and (E) an electrode spacing; and
(iii) processing program code to (1) provide a production substrate in the process chamber, and (2) maintain the selected process parameters while exposing the production substrate to energized gas in the chamber to process the production substrate.

17. A chamber according to claim 16 further comprising a sheet resistance detector capable of measuring the sheet resistance of the layer, and providing the input signal to the controller in relation to the sheet resistance.

18. A chamber according to claim 16 wherein the detection program code is capable of selecting one or more process parameters in relation to the measured sheet resistance to provide a substantially uniform flow distribution of energized gas over the production substrate.
